(19) United States
(12) Patent Application Publication
(10) Pub. No.: US 2026/0150188 A1
(43) Pub. Date: May 28, 2026

(54) CIRCUIT SUBSTRATE

(71) Applicant: VIA TECHNOLOGIES, INC., New Taipei City (TW)

(72) Inventors: Wen-Yuan CHANG, New Taipei City (TW); Yeh-Chi HSU, New Taipei City (TW); Gao-Tian LIN, New Taipei City (TW); Ping-Hsun HSIEH, New Taipei City (TW); Hung-Sen LIANG, New Taipei City (TW)

(21) Appl. No.: 19/179,407

(22) Filed: Apr. 15, 2025

(30) Foreign Application Priority Data
Nov. 27, 2024 (TW) 113145698

(51) Int. Cl. H05K 1/02; H05K 1/11

(52) U.S. Cl. CPC H05K 1/0298; H05K 1/115; H05K 2201/0195; H05K 2201/096

(57) ABSTRACT

A circuit substrate is provided. The circuit substrate includes a core substrate, first dielectric layers, second dielectric layers, and a first conductive line. The first dielectric layer is disposed on the core substrate. The first and second dielectric layers are formed of different materials and have different thicknesses. The first conductive line is disposed in the first and second dielectric layers. The first conductive line includes first and second line segments, first conductive vias stacked on each other, and second conductive vias stacked on each other. The first line segment is disposed between the first dielectric layers. The second line segment is disposed between the second dielectric layers. The first conductive vias penetrate the first dielectric layers and connect the first line segment. The second conductive vias penetrate the second dielectric layers and connect the first conductive vias and the second line segment.

### CROSS REFERENCE TO RELATED APPLICATIONS

This Application claims priority of Taiwan Patent Application No. 113145698, filed on Nov. 27, 2024, the entirety of which is incorporated by reference herein.

### BACKGROUND OF THE INVENTION

### Field of the Invention

The present disclosure relates to a circuit substrate, and, in particular, it relates to a redistribution structure of a circuit substrate.

### Description of the Related Art

In the current technology used in semiconductive packaging, there has been a continuous increase in the operating frequency and power consumption of integrated circuit chips, as well as a need for multi-chip integrated packaging and multi-input/output (I/O) terminal chips. In response, the operating frequency and routing density of printed circuit boards must increase accordingly. However, in the application of high-performance computing (HPC) printed circuit boards, maintaining good signal integrity (SI) is becoming more and more important.

Therefore, a novel printed circuit board is needed.

### BRIEF SUMMARY OF THE INVENTION

An embodiment of the disclosure provides a circuit substrate. The circuit substrate includes a core substrate, first dielectric layers, second dielectric layers, and a first conductive line. The core substrate has a first surface and a second surface opposite each other. The first dielectric layers are disposed on the first surface of the core substrate. Each of the first dielectric layers is formed of a first material and has a first thickness. The second dielectric layers are disposed on the core substrate. The first dielectric layers are disposed on the second dielectric layers. Each of the second dielectric layers is formed of a second dielectric material and has a second thickness. The first conductive line is disposed in the first dielectric layers and the second dielectric layers. The first conductive line includes a first line segment, a second line segment, first conductive vias stacked on each other, and second conductive vias stacked on each other. The first line segment is disposed between the first dielectric layers. The second line segment is disposed between the second dielectric layers. The first conductive vias penetrate the first dielectric layers. The first conductive vias are connected to the first line segment. The second conductive vias penetrate the second dielectric layers. The second conductive vias are connected to the first conductive vias and the second line segment.

### BRIEF DESCRIPTION OF THE DRAWINGS

The present invention can be more fully understood by reading the subsequent detailed description and examples with references made to the accompanying drawings, wherein:

FIG. 1 is a schematic cross-sectional view of a circuit substrate in accordance with some embodiments of the disclosure;

FIG. 2A is a schematic exploded view of conductive layers located at some levels of a circuit substrate in accordance with some embodiments of the disclosure;

FIG. 2B is an enlarged view of a portion of FIG. 2A;

FIG. 2C is an enlarged view of a portion of FIG. 2A;

FIG. 2D is an enlarged view of a portion of FIG. 2A;

FIG. 3A is a schematic exploded view of conductive layers located at some levels of a circuit substrate in accordance with some embodiments of the disclosure;

FIG. 3B is an enlarged view of a portion of FIG. 3A;

FIG. 3C is an enlarged view of a portion of FIG. 3A;

FIG. 3D is an enlarged view of a portion of FIG. 3A;

FIG. 4A is a schematic exploded view of conductive layers located at some levels of a circuit substrate in accordance with some embodiments of the disclosure.

FIG. 4B is an enlarged view of a portion of FIG. 4A;

FIG. 4C is an enlarged view of a portion of FIG. 4A;

FIG. 4D is an enlarged view of a portion of FIG. 4A;

FIG. 4E is an enlarged view of a portion of FIG. 4A;

FIG. 5 is a schematic cross-sectional view of a circuit substrate in accordance with some embodiments of the disclosure; and

FIG. 6 is a schematic cross-sectional view of a circuit substrate in accordance with some embodiments of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

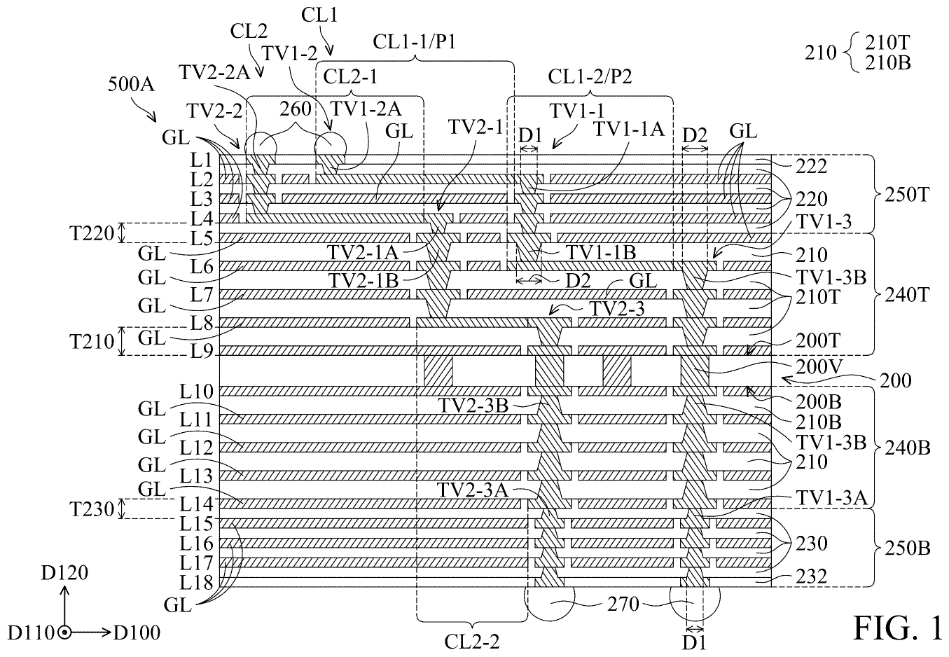

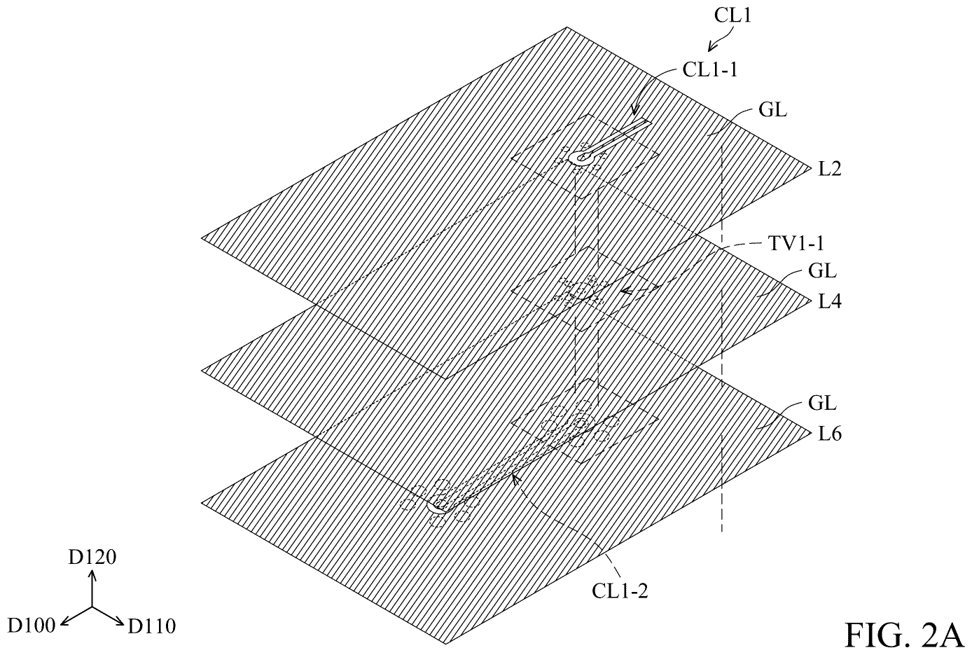

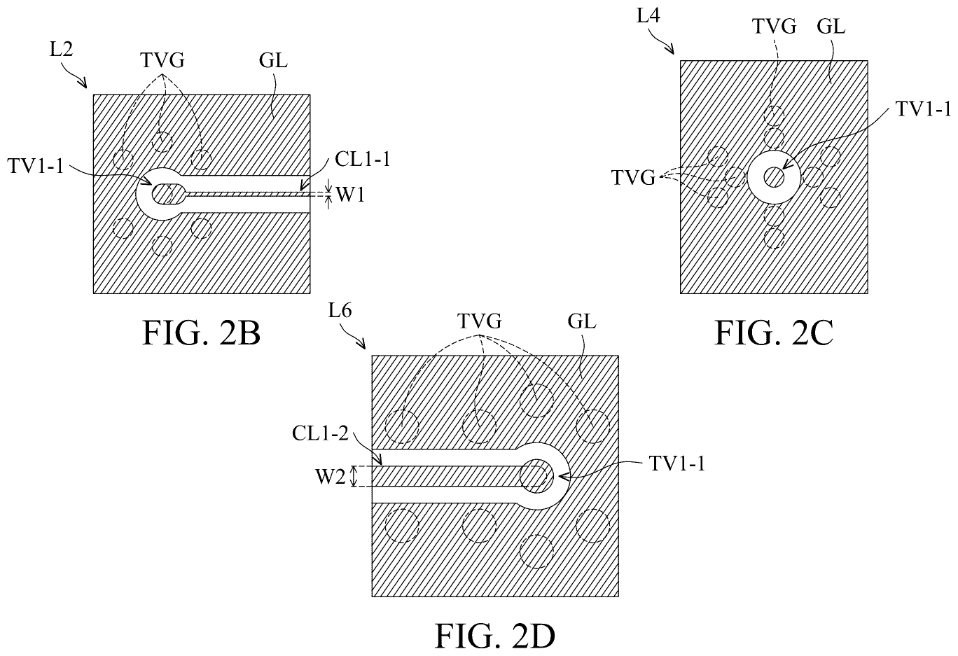

FIG. 1 is a schematic cross-sectional view of a circuit substrate 500A in accordance with some embodiments of the disclosure. FIG. 2A is a schematic exploded view of conductive layers located at some levels of the circuit substrate 500A in accordance with some embodiments of the disclosure. FIGS. 2B, 2C, and 2D are partially enlarged views of FIG. 2A, showing the arrangements of conductive lines, ground layers, and ground vias. In some embodiments, the circuit substrate 500A may be a multi-layer package substrate, and at least one integrated circuit chip and solder balls can be respectively mounted on the top and bottom surfaces of the circuit substrate 500A. As shown in FIG. 1, for illustration, the circuit substrate 500A is an 18-layer circuit substrate as an example, in which from the topmost layer to the bottommost layer are respectively marked with a level L1, a level L2, a level L3 . . . and a level L18 in sequence. Furthermore, the conductive layer located at each of the levels may include conductive lines, ground layers, or a combination thereof. The number of conductive layers of the circuit substrate 500A of the disclosure may be determined according to the designs and is not limited to the disclosed embodiment. Furthermore, in FIGS. 1, 2 and the following figures, directions D100 and D110 are defined as horizontal directions (also regarded as the extending directions of conductive lines and transmission lines), and direction D120 is defined as a vertical direction (also regarded as the extending direction of the vias).

As shown in FIG. 1, the circuit substrate 500A may include a core substrate 200, a plurality of dielectric layers 210, 220, 230 and a conductive line CL1.

The core substrate 200 has a first surface 200T and a second surface 200B opposite each other. In some embodiments, the first surface 200T may be a chip side surface, and the second surface 200B may be a solder ball side surface. In some embodiments, the core substrate 200 may be formed of paper phenolic resin, composite epoxy resin, polyimide resin, bismaleimide-triazine resin (BT resin) or glass fiber-reinforced composite materials.

The core substrate 200 also has core conductive through-holes 200V. The core conductive through-hole 200V penetrates the core substrate 200. In addition, two terminals of the core conductive through-hole 200V may be aligned with the first surface 200T and the second surface 200B of the core substrate 200 respectively. In some embodiments, the core conductive through-hole 200V may be a solid cylinder or a hollow cylinder. In some embodiments, the material of the core conductive through-hole 200V may be copper, copper alloy, or conductive metal. The core conductive through-hole 200V may be formed using a laser drilling process and an electroplating process. In some embodiments, the core conductive through-hole 200V may be a solid cylinder or a hollow cylinder filled with hole filing material. The hole filing material includes resin, silver glue, or ink.

As shown in FIG. 1, a plurality of dielectric layers 210 (including dielectric layers 210T and 210B) stacked on each other are symmetrically disposed on the first surface 200T and the second surface 200B of the core substrate 200. In other words, there are the same number of the dielectric layers 210T and 210B disposed on the first surface 200T and the second surface 200B of the core substrate 200. In this embodiment, there are four dielectric layers 210T and four dielectric layers 210B disposed on the first surface 200T and the second surface 200B of the core substrate 200, respectively. The materials of the dielectric layers 210T and 210B may include bismaleimide triazine resin (BT resin), prepreg (PP), FR-4, FR-5, or a combination thereof. The dielectric layer 210T, 210B may contain glass fibers. Therefore, the dielectric layers 210T and 210B may be formed using a lamination process. In some embodiments, each of the single dielectric layer 210T and the single dielectric layer 210B has a thickness T210.

A plurality of dielectric layers 220 stacked on each other are disposed on the dielectric layer 210T. In this embodiment, the dielectric layer 210T located on the first surface 200T of the core substrate 200 is disposed between the dielectric layer 220 and the core substrate 200. In other words, the dielectric layer 220 may be separated from the core substrate 200 by the dielectric layer 210T. In some embodiments, there are no other types of dielectric layers located between the dielectric layer 210T and the core substrate 200. In some embodiments, the material of the dielectric layer 220 may include polybenzoxazole (PBO), benzocyclobutene (BCB), polyimide (PI), Ajinomoto build-up film (ABF film), resin coated copper (RCC), or a combination thereof. The dielectric layer 220 may not contain glass fibers. Therefore, the dielectric layer 220 may be formed using a coating process or a lamination process. In some embodiments, the single dielectric layer 220 has thickness T220. It is noted that compared with the conventional processes, multiple dielectric layers stacked on each other are disposed on the same side of the core substrate are formed of the same material. However, in this embodiment, the dielectric layers 210 close to the core substrate 200 and the dielectric layer 220 away from the core substrate 200 are formed of different materials.

As shown in FIG. 1, the circuit substrate 500A further includes a plurality of dielectric layers 230 disposed on the dielectric layer 210B. In this embodiment, the dielectric layer 210B located on the second surface 200B of the core substrate 200 is disposed between the dielectric layer 230 and the core substrate 200. In other words, the dielectric layer 230 may be separated from the core substrate 200 by the dielectric layer 210B. In some embodiments, the dielectric layer 220 and the dielectric layer 230 away from the core substrate 200 may be formed of the same material. Furthermore, the thickness T230 of the single dielectric layer 230 may be the same with the thickness T220 of the single dielectric layer 220. In some embodiments, multiple build-up processes may be used to simultaneously form the dielectric layers 220 and 230 having the same number of layers (e.g., 4 layers) and symmetrical each other on opposite sides of the core substrate 200.

In some embodiments, compared to the dielectric layers 220 and 230, the dielectric layer 210 has higher mechanical strength because it contains glass fibers. Moreover, corresponding to the material and manufacturing process of the dielectric layers 210, 220, and 230, the thickness T210 of the dielectric layer 210 is different from the thickness T220 of the dielectric layer 220 and the thickness T230 of the dielectric layer 230. In some embodiments, the thickness T220 of the dielectric layer 220 and the thickness T230 of the dielectric layer 230 are thinner than the thickness T210 of the dielectric layer 210. For example, the thickness T220 of the dielectric layer 220 and the thickness T230 of the dielectric layer 230 are between about 20 μm and 40 μm. The thickness T210 of the dielectric layer 210 is greater than or equal to about 60 μm. In some embodiments, the ratio of the thickness T210 of the dielectric layer 210 to the thickness T220 of the dielectric layer 220 may be greater than or equal to 1.5. The ratio of the thickness T210 of the dielectric layer 210 to the thickness T230 of the dielectric layer 230 may be greater than or equal to 1.5.

The circuit substrate 500A also includes a plurality of conductive layers (not shown) alternately arranged with the dielectric layers 210, 220, and 230 and a plurality of conductive vias penetrating the dielectric layers 210, 220, and 230. Furthermore, the conductive line CL1 is formed by electrically connecting the conductive layers and the conductive via.

In some embodiments, the dielectric layers 210 close to the first surface 200T and the second surface 200B of the core substrate 200, the conductive layers alternately arranged with the dielectric layers 210, and the conductive vias penetrating the dielectric layers 210 form the inner redistribution structures 240T and 240B. The dielectric layers 220 away from the core substrate 200, the conductive layers alternately arranged with the dielectric layers 220, and the conductive vias penetrating the dielectric layers 220 form an outer redistribution structure 250T. Furthermore, the dielectric layers 230 away from the core substrate 200, the conductive layers alternately arranged with the dielectric layers 230, and the conductive vias penetrating the dielectric layers 230 form an outer redistribution structure 250B. In some embodiments, corresponding to the material and manufacturing process of the dielectric layers 210, 220, and 230, the routing density of the inner redistribution structures 240T and 240B is smaller than the routing density of the outer redistribution structures 250T and 250B. Moreover, the width and spacing of the conductive lines of the inner redistribution structures 240T and 240B are larger than the width and spacing of the conductive lines of the outer redistribution structures 250T and 250B.

In this embodiment, the conductive line CL1 is disposed in the inner redistribution structures 240T and 240B and the outer redistribution structures 250T and 250B. For example, the conductive line CL1 is disposed in the dielectric layers 210, 220, and 230. Moreover, two terminals of the conductive line CL1 are respectively connected to conductive bumps 260 of the integrated circuit chip (not shown) disposed above the first surface (chip side surface) 200T and solder balls 270 disposed on the second surface (the solder ball surface) 200B. In some embodiments, the conductive line CL1 includes at least two line segments CL1-1, CL1-2 and a conductive via stack TV1-1.

In this embodiment, the line segments CL1-1 and CL1-2 of the conductive line CL1 are located at the levels of the conductive layer above the first surface 200T of the core substrate 200. The line segment CL1-1 is located in the outer redistribution structure 250T and disposed between adjacent dielectric layers 220. The line segment CL1-2 is located in the inner redistribution structure 240T and disposed between adjacent dielectric layers 210T. For example, the line segment CL1-1 is formed by the conductive layer located at the level L2. The line segment CL1-2 is formed by the conductive layer located at the level L6. In some embodiments, the line segment CL1-1 has a line length P1 and a line width W1, and the line segment CL1-2 has a line length P2 and a line width W2.

The line segments CL1-1 and CL1-2 of the conductive line CL1 may extend in the horizontal direction (the direction D100) and do not overlap with each other in the vertical direction (the direction D120). In some embodiments, the line segments CL1-1 and the line segments CL1-2 of the conductive line CL1 may be connected to each other through the conductive via stack TV1-1.

In some embodiments, the conductive via stack TV1-1 includes conductive vias TV1-1A and TV1-1B stacked on each other along the direction D120. The conductive vias TV1-1A are located in the outer redistribution structure 250T and penetrate the dielectric layers 220. The conductive vias TV1-1B are located in the inner redistribution structure 240T and penetrate the dielectric layer 210T. The conductive vias TV1-1A, TV1-1B overlap each other in the direction D120. In some embodiments, the conductive vias TV1-1A and TV1-1B do not overlap each other in the direction D120 due to design demands. Alternatively, the number of stacked conductive vias TV1-1A, TV1-1B may be limited, depending on the requirements. In some embodiments, the conductive vias TV1-1A are connected to one terminal of the line segment CL1-1, and the conductive vias TV1-1B are connected to the conductive vias TV1-1A and one terminal of the line segment CL1-2. As shown in FIG. 1, in some embodiments, the cross-sectional shapes of the conductive vias TV1-1A and TV1-1B are tapered. The diameter D1 of the conductive via TV1-1A becomes narrower toward the core substrate 200. Furthermore, the diameter D2 of the conductive via TV1-1B is larger than the diameter D1 of the conductive via TV1-1A, and becomes narrower toward the core substrate 200.

In some embodiments, the conductive line CL1 may further include a conductive via stack TV1-2. Two terminals of the conductive via stack TV1-2 are connected to the line segment CL1-1 and the conductive bump 260 respectively. Moreover, opposite terminals of the line segment CL1-1 are respectively connected to the conductive via stacks TV1-1, TV1-2. In some embodiments, the conductive via stack TV1-2 includes one or more conductive vias TV1-2A. In some embodiments, the conductive via TV1-1A and the conductive via TV1-2A may have the same structure. Furthermore, the number of conductive vias TV1-2A depends on the number of dielectric layers disposed between the conductive bumps 260 and the line segment CL1-1, and is not limited to the disclosed embodiment. In this embodiment, the number of the conductive vias TV1-2A is 1.

In some embodiments, the line segment CL1-1 of the conductive line CL1 is connected to the conductive bump 260 directly by the conductive via TV1-2A. In other words, there is no other line segment located in the outer redistribution structure 250T and between the line segment CL1-1 of the conductive line CL1 and the conductive bump 260.

In some embodiments, the conductive line CL1 may further include conductive via stacks TV1-3. Two terminals of the conductive via stack TV1-3 are connected to the line segment CL1-2 and the solder ball 270 respectively. Moreover, the opposite terminals of the line segment CL1-2 are respectively connected to the conductive via stacks TV1-1, TV1-3. In some embodiments, the conductive via stack TV1-3 includes conductive vias TV1-3A, TV1-3B stacked on each other along the direction D120. When the line segment CL1-2 is disposed above the first surface 200T of the core substrate 200, the conductive vias TV 1-3B stacked on each other may be located in the inner redistribution structures 240T, 240B and penetrate the dielectric layers 210T, 210B. Therefore, the core conductive through-hole 200V is located between the two conductive vias TV1-3B. The conductive vias TV1-3A stacked on each other may be located in the outer redistribution structure 250B and penetrate the dielectric layers 230. The conductive vias TV1-3A and TV1-3B overlap each other in the direction D120. In some embodiments, the conductive vias TV1-1A and the conductive vias TV1-3A may have similar structures and sizes. The diameter of the conductive via TV1-3A is equal to the diameter D1 of the conductive via TV1-1A, and becomes narrower toward the core substrate 200. In some embodiments, the conductive vias TV1-1B and the conductive vias TV1-3B may have similar structures and sizes. In addition, the conductive vias TV1-1B and the conductive vias TV1-3B may be arranged in a mirror symmetrical configuration. The diameter of the conductive via TV1-3B located in the inner redistribution structure 240T is equal to the diameter D2 of the conductive via TV1-1B, and becomes narrower toward the core substrate 200. In addition, the diameter of the conductive via TV1-3B located in the inner redistribution structure 240B is equal to the diameter D2 of the conductive via TV1-1B, and becomes narrower toward the core substrate 200. Furthermore, the number of the conductive vias TV1-3A and TV1-3B depends on the number of dielectric layers 210 and 230 disposed between the solder ball 270 and the line segment CL1-2, and is not limited to the disclosed embodiment. In this embodiment, the number of the conductive vias TV 1-3A is 4, and the number of the conductive vias TV 1-3B is 7.

In some embodiments, the line segment CL1-2 of the conductive line CL1 is electrically connected to the solder ball 270 directly by the conductive vias TV1-3A and TV1-3B. In other words, there is no other line segment located in the outer redistribution structure 250B between the line segment CL1-2 of the conductive line CL1 and the solder ball 270, but it is not limited to this embodiment.

Since the line width and spacing of the outer redistribution structure 250T are smaller than the line width and spacing of the inner redistribution structure 240T. Therefore, in the conductive line CL1, the line width W2 of the line segment CL1-2 is greater than the line width W1 of the line segment CL1-1, the diameter D2 of the conductive via TV1-1B is greater than the diameter D1 of the conductive via TV1-1A. Therefore, electrical performance such as impedance matching, reflection coefficient and insertion loss are improved. On the other hand, in the conductive line CL1, the line width W1 of the line segment CL1-1 is smaller than the line width W2 of the line segment CL1-2, and the diameter D1 of the conductive via TV1-2A is smaller than the diameter D2 of the conductive via TV1-1B. Therefore, the line segment CL1-1 and the conductive via TV1-2A of the conductive line CL1 are suitable to be electrical connected to the integrated circuit chips having smaller line widths. In other words, since the conductive line CL1 is composed of the conductive layers located at two or more different levels, when the signal is transmitted through the conductive line CL1, the signal is transmitted through at least two kinds of dielectric layers 210 and 220. The line segment CL1-1 in the dielectric layers 220 has a narrower line width, so it is suitable for connecting to the integrated circuit chips. In addition, the line segment CL1-2 of the dielectric layer 210 has a wider line width, which may be used to improve electrical performance such as impedance matching, reflection coefficient and insertion loss. In some embodiments, the line length P1 of the line segment CL1-1 may be greater than, less than, or equal to the line length P2 of the line segment CL1-2. For example, the line length P2 of the line segment CL1-2 is between about 20% and 85% of the sum of the line lengths P1 and P2 (P1+P2). If the line length P2 of line segment CL1-2 is less than 20% of the sum of line lengths P1 and P2 (P1+P2), the improvement of electrical performance is not significant. If the line length P2 of line segment CL1-2 it is greater than 85% of the sum of the line lengths P1 and P2 (P1+P2), the area occupied by the conductive line CL1 will be too large, which will increase the area and the fabrication cost of the circuit substrate 500A.

The conductive layer of the circuit substrate 500A also includes a plurality of ground layers GL located at the levels L1, L2 . . . or L18. In some embodiments, some of the ground layers GL are located at adjacent levels above and below the line segments CL1-1 and CL1-2 (for example, the levels L1, L3, L5, L7). The ground layers GL are located directly above or directly below the line segments CL1-1 and CL1-2. In addition, the projections (the vertical projections) of the line segments CL1-1 and CL1-2 in the direction D120 will be located within the ground layers GL located at adjacent levels.

In some embodiments, some of the ground layers GL may be located at other levels (e.g., the level L4) between the line segments CL1-1 and CL1-2. The ground layers GL may be disposed between the dielectric layers 210, 220, and 230, depending on the levels where the line segments CL1-1 and CL1-2 are located at. Moreover, the ground layers GL may surround the conductive vias TV1-1A, TV1-1B, TV1-2A, TV1-3A, and TV1-3B used to connect the line segments CL1-1 and CL1-2.

In some embodiments, some of the ground layers GL may also be located at the same level as the line segments CL1-1 and CL1-2 (for example, the levels L2 and L6). For example, the ground layer GL located at level L2 has an opening (not shown) corresponding to the line segment CL1-1, so as to be separated from and surround the line segment CL1-1. The ground layer GL located at level L6 has an opening (not shown) corresponding to the line segment CL1-2, so as to be separated from and surround the line segment CL1-2. In this way, the line segments CL1-1 and CL1-2 may be disposed between the ground layers GL in both the horizontal direction (the directions D100 and D110) and the vertical direction (the direction D120).

In some embodiments, the circuit substrate 500A further includes a plurality of ground vias TVG stacked on each other (FIGS. 2A, 2B, 2C, and 2D). The ground vias TVG penetrate the dielectric layers 210, 220, and 230 and surround the conductive vias TV1-1A, TV1-1B, TV1-2A, TV1-3A, and TV1-3B to connect the ground layers GL surrounding the line segments CL1-1, CL1-2 and the conductive vias V1-1A, TV1-1B, TV1-2A, TV1-3A, and TV1-3B. For example, the ground via TVG may connect the ground layers GL at the levels L1, L2 . . . L18.

In some embodiments, the projections (the vertical projection) of the ground vias TVG in the direction D120 may be separated from each other and surround the terminals of the line segments CL1-1, CL1-2 and the conductive vias TV1-1A, TV1-1B, TV1-2A, TV1-3A, and TV1-3B. Moreover, the ground vias TVG may have a symmetrical arrangement relative to the terminals of the line segments CL1-1 and CL1-2 and the conductive vias TV1-1A, TV1-1B, TV1-2A, TV1-3A, and TV1-3B.

The circuit substrate 500A may further include a conductive line CL2 disposed side by side with the conductive line CL1.

Similar to the conductive line CL1, the conductive line CL2 is disposed in the inner redistribution structures 240T, 240B and the outer redistribution structures 250T, 250B. In this embodiment, the conductive lines CL1 and CL2 may be separated from each other by the ground layers GL and the ground vias TVG. Moreover, two terminals of the conductive line CL2 are respectively connected to another conductive bump 260 of the integrated circuit chip (not shown) disposed above the first surface (the chip side surface) 200T and another solder ball 270 disposed above the second surface (the solder ball surface) 200B. In some embodiments, the conductive line CL2 includes line segments CL2-1, CL2-2 and conductive via stacks TV2-1, TV2-2, TV2-3.

The line segments CL2-1 and CL2-2 of the conductive line CL2 are respectively located in the outer redistribution structure 250T and the inner redistribution structure 240T on the first surface 200T of the core substrate 200. Moreover, the line segments CL2-1 and CL2-2 are respectively disposed between the dielectric layers 220 and between the dielectric layers 210, and the dielectric layers 220 and 210 are suitable for different line width processes. In this embodiment, the line segments CL2-1 and CL2-2 of the conductive line CL2 and the line segments CL1-1 and CL1-2 of the conductive line CL1 are located at different levels. For example, the line segment CL2-1 is located below the line segment CL1-1, and is formed by the conductive layer located at the level L4. The line segment CL2-2 is located below the line segment CL1-2, and is formed by the conductive layer located at the level L8. In the vertical direction (the direction D120), at least one ground layer GL may be disposed between the line segments CL1-1 and CL1-2 and between the line segments CL2-1 and CL2-2 to ensure that the line segments CL1-1 and CL1-2 of the conductive line CL1 and the line segments CL2-1 and CL2-2 of the conductive line CL2 are all covered by the ground layers GL located at upper and lower adjacent levels. In some embodiments, the line segments CL1-1 and CL1-2 of the conductive line CL1 and the line segments CL2-1 and CL2-2 of the conductive line CL2 have the same or similar relative size relationship.

Similarly, the line segments CL2-1 and CL2-2 of the conductive line CL2 may be connected to each other by the conductive via stack TV2-1. The line segment CL2-1 of the conductive line CL2 and the conductive bump 260 may be connected to each other by the conductive via stack TV2-2. The line segment CL2-2 of the conductive line CL2 and the solder ball 270 may be connected to each other by the conductive via stack TV2-3.

In this embodiment, the conductive via stacks TV1-1, TV1-2, and TV1-3 and the conductive via stacks TV2-1, TV2-2, and TV2-3 may be surrounded by the ground vias TVG located in the corresponding dielectric layers. In the horizontal direction, the conductive via stacks TV1-1, TV1-2, and TV1-3 may be separated from the conductive via stacks TV2-1, TV2-2, and TV2-3 by the ground vias TVG.

In some embodiments, the conductive via stacks TV1-1, TV1-2, and TV1-3 and the conductive via stacks TV2-1, TV2-2, and TV2-3 may have similar structures. For example, the conductive via stack TV2-1 includes conductive vias TV2-1A, TV2-1B stacked on each other along the direction D120. The conductive via stack TV2-2 includes one or more conductive vias TV2-2A. The conductive via stack TV2-3 includes conductive vias TV2-3A, TV2-3B stacked on each other along the direction D120. In some embodiments, the conductive vias TV2-1A, TV2-1B and the conductive vias TV1-1A, TV1-1B have the same or similar structures. The conductive vias TV2-2A and the conductive vias TV1-2A have the same or similar structures. The conductive vias TV2-3A and TV2-3B and the conductive vias TV1-3A and TV1-3B have the same or similar structures. In some embodiments, the number and composition of the conductive vias included in the conductive via stacks TV2-1, TV2-2, and TV2-3 respectively depend on the levels where the line segments CL2-1 and CL2-2 are located at, and not limited to the disclosed embodiments.

The circuit substrate 500A also includes solder mask layers 222 and 232 located on the first surface 200T and the second surface 200B. The solder mask layers 222 and 232 cover portions of the outer redistribution structures 250T and 250B, and may have one or more openings. The openings expose portions of the conductive lines CL1 and CL2, and may provide the formation positions of the subsequent formed conductive bumps 260 and solder balls 270. In some embodiments, the solder mask layers 222 and 232 may include a solder mask material such as green paint, or an insulating material including polyimide, Ajinomoto build-up film (ABF film), epoxy resin, acrylic resin or a composite of the former two, or polypropylene (PP). The solder mask layers 222 and 232 may be formed by coating, printing, pasting, laminating, or other applicable processes.

In some embodiments, the conductive lines CL1 and CL2 may have different arrangements depending on the signal transmission methods. In this embodiment, the conductive lines CL1 or CL2 may be used to transmit single-ended signals. Specifically, the conductive lines CL1 and CL2 may respectively include a single transmission line coupled to the transmission port or the reception port, respectively for transmitting signals from the transmission port or to the reception port.

Since the conductive lines coupled to the reception port have stricter requirements for signal integrity (SI), when the conductive line CL1 is coupled to the transmission port and the conductive line CL2 is coupled to the reception port, the line length of line segment CL2-2 located in the inner redistribution structure 240T having a thick line width may be longer than the line length P2 of line segment CL1-2 to further improve impedance mismatch or insertion loss and improve signal integrity for reception signal.

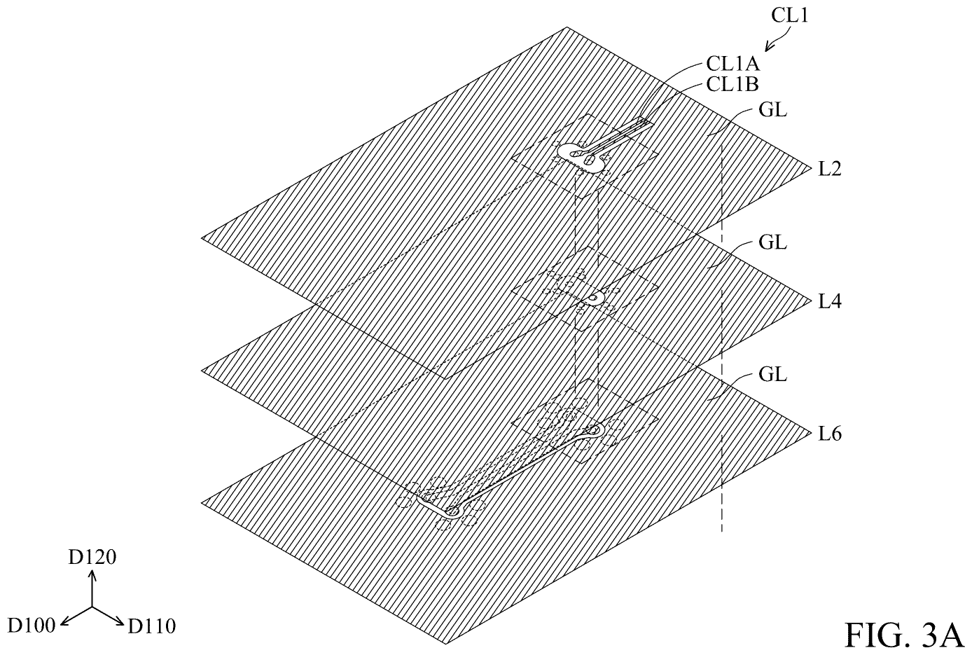

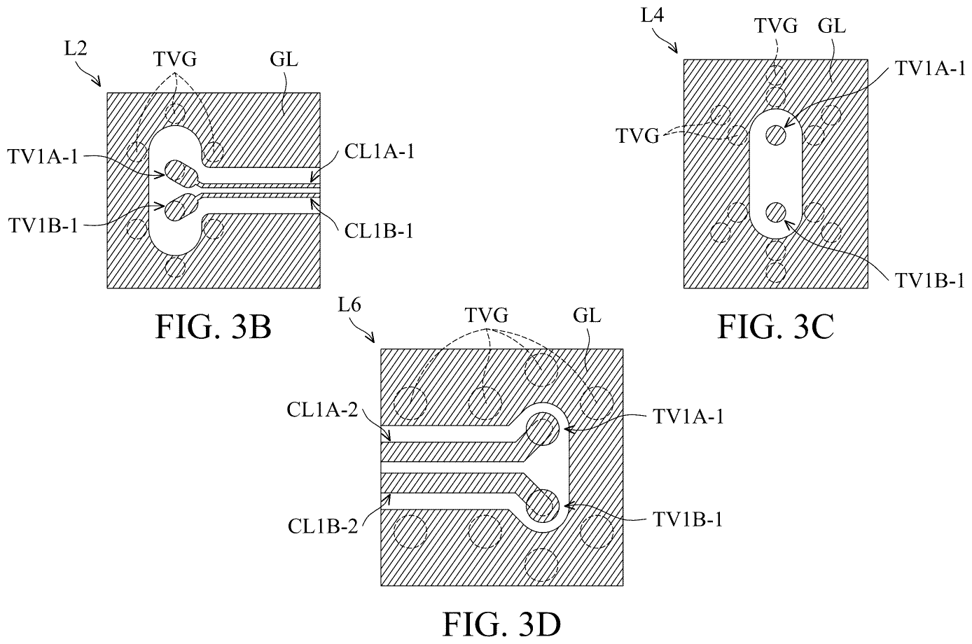

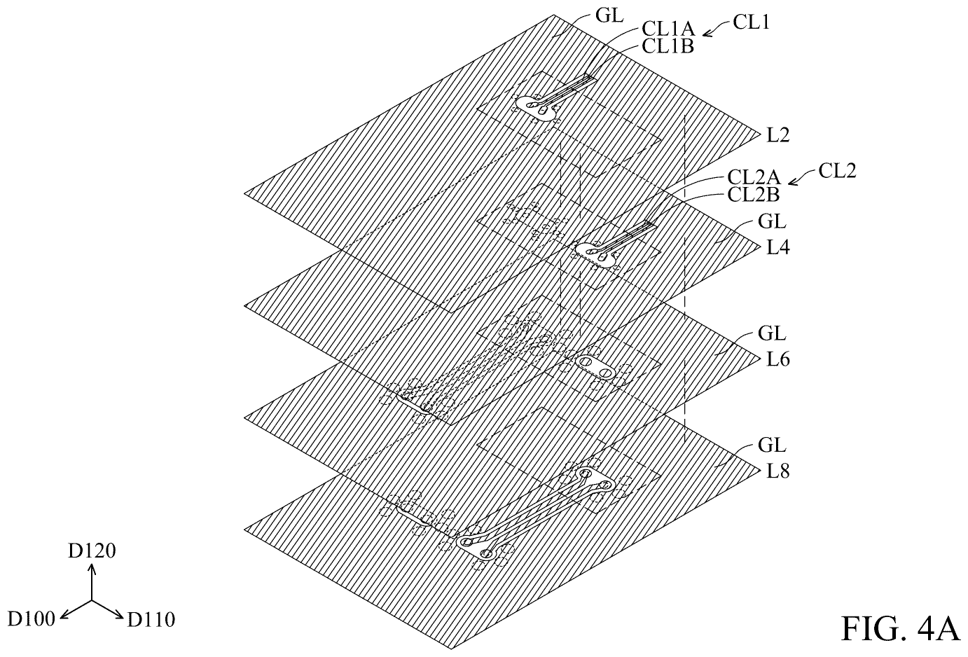

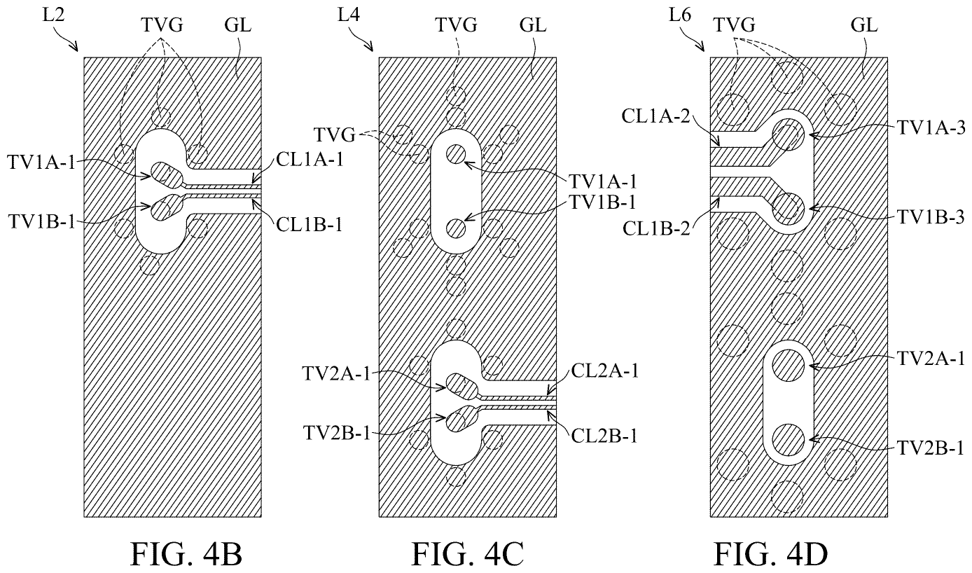

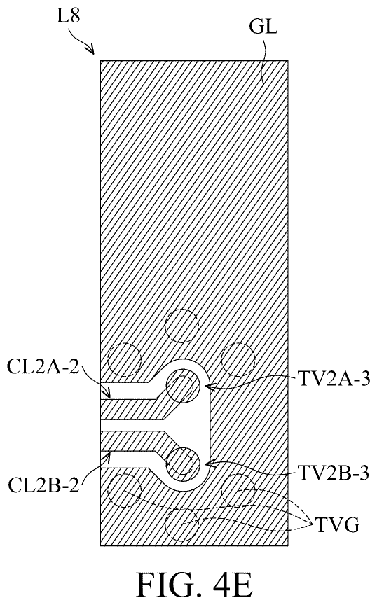

In some embodiments shown in FIGS. 3A to 3D and 4A to 4E, the conductive line CL1 (or the conductive line CL2) may be used to transmit differential signals.

FIG. 3A is a schematic exploded view of the conductive layers at some levels of the circuit substrate 500A in accordance with some embodiments of the disclosure. FIGS. 3B, 3C, and 3D are partially enlarged views of FIG. 3A, showing the arrangements of conductive lines, ground layers, and ground vias, in which the reference numbers the same or similar to those in FIGS. 1 and 2A to 2D denote the same or similar elements. In this embodiment, the conductive line CL1 of the circuit substrate 500A may include a pair of conductive lines CL1A, CL1B. In the horizontal direction, the conductive lines CL1A and CL1B are arranged side by side. The conductive lines CL1A and CL1B are located at the same level. There is no ground layer GL and ground via TVG located between the conductive line CL1A and the conductive line CL1B. The conductive line CL2 of the circuit substrate 500A have similar structure as the conductive line CL1, and the details are not repeated herein.

In some embodiments, the conductive lines CL1A and CL1B respectively have the same or similar structure as the conductive line CL1. For example, the conductive line CL1A includes line segments CL1A-1, CL1A-2 and a conductive via stack TV1A-1. The conductive line CL1B includes line segments CL1B-1, CL1B-2 and a conductive via stack TV1B-1. In this embodiment, the line segments CL1A-1 and CL1B-1 may be located at the same level, have the same size, and their projections are substantially parallel with each other. The line segments CL1A-2 and CL1B-2 may be located at the same level, have the same size, and their projections are substantially parallel with each other. The conductive via stacks TV1A-1 and TV1B-1 may include the same number of conductive vias and are substantially parallel with each other.

In this embodiment, the pair of conductive lines CL1A and CL1B may both be coupled to the same transmission port or the same reception port to form a pair of differential signal transmission lines.

FIG. 4A is a schematic exploded view of the conductive layers at some levels of the circuit substrate 500A in accordance with some embodiments of the disclosure. FIGS. 4B, 4C, 4D, and 4E are partially enlarged views of FIG. 4A, showing the arrangements of conductive lines, ground layers, and ground vias, in which the reference numbers the same or similar to those in FIGS. 1, 2A to 2D, and 3A to 3D denote the same or similar elements. In this embodiment, the conductive line CL1 of the circuit substrate 500A may include two pairs of conductive lines, including a first pair of conductive lines CL1A and CL1B. The conductive lines CL1A and CL1B are located at the same level. In addition, the conductive line CL2 of the circuit substrate 500A may include a second pair of conductive lines CL2A and CL2B. The conductive lines CL2A and CL2B are located at the same levels. However, The conductive lines CL1 and CL2 are located at the different levels.

In some embodiments, the line segments CL1A-1 and CL1B-1 of the first pair of conductive lines CL1A and CL1B may be located at the level different from the line segments CL2A-1 and CL2B-1 of the second pair of conductive lines CL2A and CL2B. The line segments CL1A-2 and CL1B-2 of the first pair of conductive lines CL1A and CL1B may be located at the level different from the line segments CL2A-2 and CL2B-2 of the second pair of conductive lines CL2A and CL2B. For example, the line segments CL1A-1 and CL1B-1 of the first pair of conductive lines CL1A and CL1B are located at the level L2. In addition, the line segments CL2A-1 and CL2B-1 of the second pair of conductive lines CL2A and CL2B are located at the level L4. Moreover, the line segments CL1A-2 and CL1B-2 of the first pair of conductive lines CL1A and CL1B are located at the level L6. Furthermore, the line segments CL2A-2 and CL2B-2 of the second pair of conductive lines CL2A and CL2B are located at the level L8.

In other embodiments, the line segments CL1A-1 and CL1B-1 of the first pair of conductive lines CL1A and CL1B may be located on the same level as the line segments CL2A-1 and CL2B-1 of the second pair of conductive lines CL2A and CL2B. The line segments CL1A-2 and CL1B-2 of the first pair of conductive lines CL1A and CL1B may be at the same level as the line segments CL2A-2 and CL2B-2 of the second pair of conductive lines CL2A and CL2B. In the horizontal direction, the conductive lines CL1A, CL1B, CL2A, and CL2B are arranged side by side. The conductive lines CL1A and CL1B are separated from the conductive lines CL2A and CL2B by the ground layer GL and the ground vias TVG. In the horizontal direction (for example, the direction D110), multiple ground vias TVG (for example, two ground vias TVG) are disposed between the conductive lines CL1B and CL2A in different pairs of conductive lines and adjacent to each other. There is no ground layer GL and ground via TVG disposed between the conductive line CL1A and the conductive line CL1B. Furthermore, there is no ground layer GL and ground via TVG disposed between the conductive line CL2A and the conductive line CL2B. The aforementioned description is only an illustration of the embodiments and is not intended to limit the disclosure.

In some embodiments, the first pair of conductive lines CL1A, CL1B may have the same or similar structure as the conductive line CL1. For example, the conductive line CL1A includes line segments CL1A-1 and CL1A-2 and conductive via stacks TV1A-1 and TV1A-3. The conductive line CL1B includes line segments CL1B-1, CL1B-2 and conductive via stacks TV1B-1, TV1B-3. The second pair of conductive lines CL2A, CL2B may have the same or similar structure as the conductive line CL2. For example, the conductive line CL2A includes line segments CL2A-1 and CL2A-2 and conductive via stacks TV2A-1 and TV2A-3. The conductive line CL2B includes line segments CL2B-1 and CL2B-2 and conductive via stacks TV2B-1 and TV2B-3.

In this embodiment, the first pair of conductive lines CL1A and CL1B may both be coupled to the transmission port to form a first pair of differential signal transmission lines. The second pair of conductive lines CL2A and CL2B may both be coupled to the reception port to form a second pair of differential signal transmission lines. In another embodiment, the types of the signals transmitted by the two pairs of conductive lines may be opposite.

When the first pair of conductive lines CL1A and CL1B are both coupled to the transmission port and the second pair of conductive lines CL2A and CL2B are both coupled to the reception port, the line length of the line segments CL2A-2 and CL2B-2 located in the inner redistribution structure 240T having a wider line width may be longer than the line length of line segments CL1A-2 and CL1B-2 to further improve impedance mismatch or insertion loss and improve signal integrity.

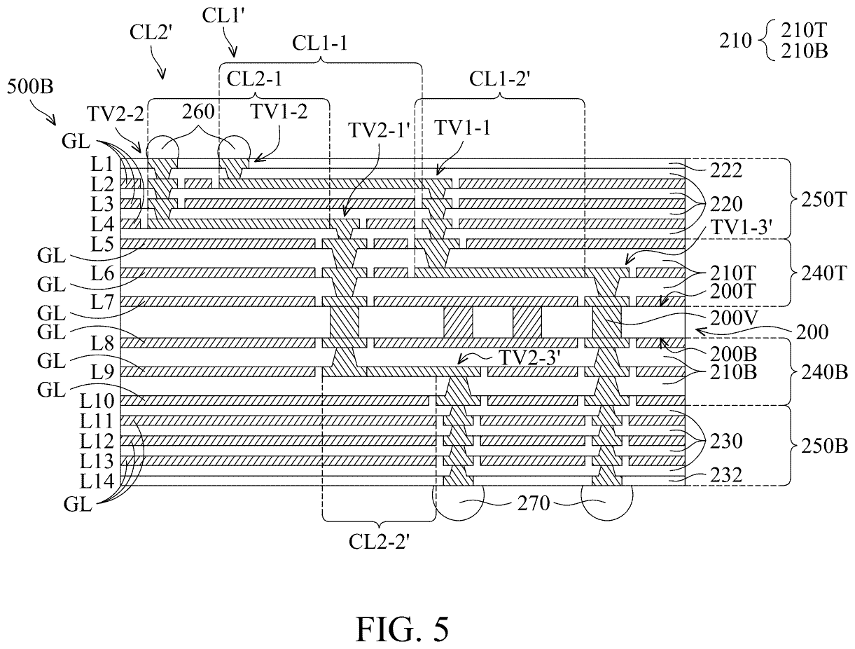

FIG. 5 is a schematic cross-sectional view of a circuit substrate 500B in accordance with some embodiments of the disclosure, in which the reference numbers the same or similar to those in FIGS. 1, 2A to 2D, 3A to 3D, and 4A to 4E denote the same or similar elements. At least one difference between the circuit substrate 500A (FIG. 1) and the circuit substrate 500B (FIG. 5) is that the line segments of the conductive lines of the circuit substrate 500B located in the dielectric layers of different materials are respectively located on the opposite surface of the core substrate.

As shown in FIG. 5, the circuit substrate 500B includes conductive lines CL1′ and CL2′. The conductive line CL1′ includes line segments CL1-1 and CL1-2′ and conductive via stacks TV1-1, TV1-2 and TV1-3′. The conductive line CL2′ includes line segments CL2-1 and CL2-2′ and conductive via stacks TV2-1′, TV2-2, and TV2-3′.

In some embodiments, the conductive line CL1 (FIG. 1) and conductive line CL1′ may have similar structures. The line segments CL1-1 and CL1-2′ of the conductive line CL1′ are both located on the first surface 200T of the core substrate 200.

In the conductive line CL2′ of the circuit substrate 500B, the line segment CL2-1 disposed in the outer redistribution structure 250T having a narrower line width and the line segment CL2-2′ disposed in the inner redistribution structure 240B having a wider line width are respectively located on the first surface 200T and the second surface 200B of the core substrate 200. In this embodiment, the conductive via stack TV2-1′ used to connect the line segment CL2-1 and the line segment CL2-2′ may be connected to the core conductive through-hole 200V. Moreover, the line segment CL 1-2′ of the conductive line CL1′ and the line segment CL2-2′ of the conductive line CL2′ may be separated from each other by the ground layers GL formed on the first surface 200T and the second surface 200B of the core substrate 200.

According to the arrangements of the line segments CL2-1 and CL2-2′ of the conductive line CL2′ in this embodiment, the number of dielectric layers 210 in the inner redistribution structures 240T and 240B may be further reduced. Moreover, the number of conductive vias stacked in the dielectric layer 210 may be further reduced. For example, compared with the circuit substrate 500A, the total number of dielectric layers 210 of the inner redistribution structures 240T and 240B of the circuit substrate 500B may be reduced from 8 to 4. In detail, the number of dielectric layers 210T and 210B located on the core substrate 200 may be reduced from 4 to 2 respectively. In the conductive via stack TV 1-3′ of the conductive line CL1′ and the conductive via stack TV2-3′ of the conductive line CL2″, the number of conductive vias penetrating the dielectric layers 210 will also be reduced accordingly. Therefore, the total number of conductive layers of the circuit substrate 500B may be reduced from 18 to 14. In addition, the total number of conductive layers of the inner redistribution structures 240T and 240B of the circuit substrate 500B may be reduced from 10 to 6, which may effectively reduce the fabrication cost.

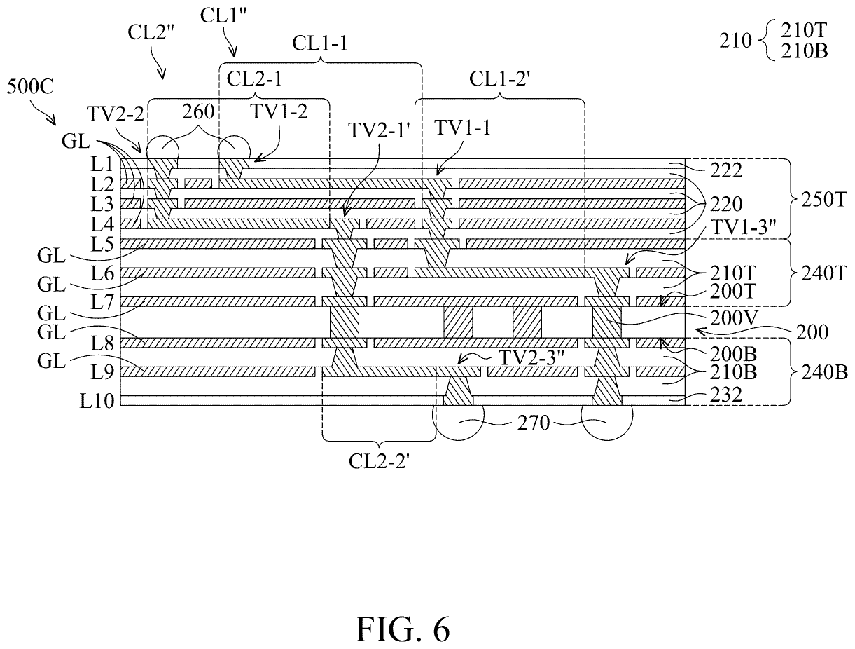

FIG. 6 is a schematic cross-sectional view of a circuit substrate 500C in accordance with some embodiments of the disclosure, in which the reference numbers the same or similar to those in FIGS. 1, 2A to 2D, 3A to 3D, 4A to 4E, and 5 denote the same or similar elements. At least one difference between the circuit substrate 500B (FIG. 5) and the circuit substrate 500C (FIG. 6) is that there are asymmetrical build-up layers formed on the first surface 200T and the second surface 200B of the core substrate 200 of the circuit substrate 500C.

As shown in FIG. 6, the circuit substrate 500C includes conductive lines CL1″ and CL2″. The conductive line CL1″ includes line segments CL1-1 and CL1-2′ and conductive via stacks TV1-1, TV1-2 and TV1-3″. The conductive line CL2″ includes line segments CL2-1 and CL2-2′ and conductive via stacks TV2-1′, TV2-2, and TV2-3″.

In the conductive lines CL1″ and CL2″, there are no other horizontal conductive line segments disposed between the line segments CL1-2′ and CL2-2′ located in the inner redistribution structures 240T and 240B and the correspond solder balls 270 located on the second surface 200B of the core substrate 200. The aforementioned description is only an illustration of the embodiments and is not intended to limit the disclosure. It may be seen from the above that only the inner redistribution structure 240B having a wider line width is disposed on the second surface 200B of the core substrate 200. No outer wiring structure is required to be disposed on the second surface 200B of the core substrate 200. At this time, the circuit substrate 500C is an asymmetric substrate with a different numbers of dielectric layers on the opposite sides of the core substrate 200.

Because only the inner redistribution structure 240B is disposed on the second surface 200B of the circuit substrate 500C, the conductive via stack TV1-3″ of the conductive line CL1″ and the conductive via stack TV2-3″ of the conductive line CL2″ may be formed by the conductive vias penetrating the dielectric layers 210 only. Therefore, the number of conductive vias in the conductive via stack connected to the solder balls 270 may be further reduced. Moreover, the total number of dielectric layers on the two sides of the core substrate 200 may be further reduced. For example, compared with the circuit substrate 500B, the total number of dielectric layers 220 on both sides of the core substrate 200 of the circuit substrate 500C may be reduced from 8 to 4. Therefore, the total number of conductive layers of the circuit substrate 500C may be reduced from 14 to 10, which may effectively reduce the fabrication cost.

Embodiments of the disclosure provide a circuit substrate. The circuit substrate includes a core substrate, first dielectric layers, second dielectric layers, and a first conductive line. The first dielectric layers are disposed on the first surface of the core substrate. Each of the first dielectric layers is formed of a first material and has a first thickness. The second dielectric layers are disposed on the core substrate. The first dielectric layers are disposed on the second dielectric layers. Each of the second dielectric layers is formed of a second material and has a second thickness. The first conductive line is disposed in the first dielectric layers and the second dielectric layers. The first conductive line includes a first line segment, a second line segment, first conductive vias stacked on each other, and second conductive vias stacked on each other. The first line segment is disposed between the first dielectric layers. The second line segment is disposed between the second dielectric layers. The first conductive vias penetrate the first dielectric layers and are connected to the first line segments. The second conductive vias penetrate the second dielectric layers and are connected to the first conductive vias and the second line segments.

In some embodiments, the conductive line has at least two line segments respectively located on two types of dielectric layers with different materials. The first dielectric layer has a higher cost and is suitable for a fine line width/spacing process as a build-up layer for the external redistribution structure, and a second dielectric layer has a lower cost and is suitable for a wide line width/spacing process as a build-up layer for the internal redistribution structure to form a hybrid circuit substrate. In the first conductive line of the circuit substrate, the first line segment disposed between the first dielectric layers has a narrower line width corresponding to the size and spacing of the conductive bumps of the integrated circuit chip. The second line segment disposed between the second dielectric layers has a wider line width, which may reduce insertion loss and maintain signal integrity without increasing additional costs when transmitting high-speed signals.

In some embodiments, the first dielectric layer and the second dielectric layer are formed of different materials. Depending on the materials and corresponding processes of the first dielectric layer and the second dielectric layer, the ratio of the second thickness of the second dielectric layer to the first thickness of the first dielectric layer may be greater than or equal to 1.5.

In some embodiments, the second line segment is disposed on the first surface or the second surface of the core substrate. When the second line segment is disposed on the second surface of the core substrate, the number of second dielectric layers may be further reduced to reduce fabrication costs.

In some embodiments, the circuit substrate has symmetrical build-up layers (including the inner redistribution structures and the outer redistribution structures) on the first surface and the second surface of the core substrate. In some embodiments, the circuit substrate has asymmetric build-up layers on the first surface and the second surface of the core substrate. For example, the circuit substrate has an inner redistribution structure and an outer redistribution structure disposed on the first surface of the core substrate of the circuit substrate, and only has an inner redistribution structure disposed on the second surface of the core substrate, which may effectively reduce the fabrication cost.

In some embodiments, the ratio of the length of the first line segment to the length of the second line segment of the first conductive line may be adjusted to meet the requirements of impedance matching and signal integrity.

In some embodiments, the conductive lines may have different arrangements depending on the signal transmission methods. In some embodiments, the first conductive line is used to transmit single-ended signals. For example, the first conductive line is a single transmission line coupled to the transmission port, for transmitting signals from the transmission port. Alternatively, the first conductive line is a single transmission line coupled to the reception port, for transmitting signals to the reception port.

In some embodiments, the circuit substrate may further include a second conductive line disposed in the first dielectric layers and the second dielectric layers. The second conductive line includes a third line segment and a fourth line segment. The third line segment is disposed between the first dielectric layers. A projection of the third line segment is substantially parallel with a projection of the first line segment. The fourth line segment is disposed between the second dielectric layers. A projection of the fourth line segment is substantially parallel with a projection of the second line segment. The first conductive line and the second conductive line may have similar structures. The first conductive line and the second conductive line are respectively used to transmit single-ended signals. For example, the first conductive line is a single transmission line coupled to the transmission port for transmitting the first signal transmitted from the transmission port. The second conductive line is a single transmission line coupled to the reception port, for transmitting the second signal to the reception port. In this embodiment, the first conductive line and the second conductive line may be separated from each other by a ground layer and a ground via.

In some embodiments in which the first conductive line and the second conductive line are located at different levels, the circuit substrate may further include a third conductive line and a fourth conductive line. The third conductive line is disposed in the first dielectric layers and the second dielectric layers. The third conductive line is substantially parallel with the first conductive line. The first conductive line has the same structure as the third conductive line. The fourth conductive line is disposed in the first dielectric layers and the second dielectric layers. The fourth conductive line is substantially parallel with the second conductive line. The second conductive line has the same structure as the fourth conductive line. In some embodiments, both the first conductive line and the third conductive line are coupled to the transmission port to form a first pair of differential signal transmission lines. The second conductive line and the fourth conductive line are both coupled to the reception port to form a second pair of differential signal transmission lines. In this embodiment, the first conductive line and the third conductive line are separated from the second conductive line and the fourth conductive line by the ground layer and the ground via. In the horizontal direction, the ground via is disposed between adjacent conductive lines (for example, the second conductive line and the third conductive line) in different pairs of conductive lines and adjacent to each other. There may be no ground layer or ground via disposed between the first conductive line and the third conductive line. Furthermore, there may be no ground layer or ground via disposed between the second conductive line and the fourth conductive line.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A circuit substrate, comprising:
a core substrate having a first surface and a second surface opposite each other;
first dielectric layers disposed on the first surface of the core substrate, wherein each of the first dielectric layers is formed of a first material and has a first thickness;
second dielectric layers disposed on the core substrate, wherein the first dielectric layers are disposed on the second dielectric layers, and each of the second dielectric layers is formed of a second dielectric material and has a second thickness; and
a first conductive line disposed in the first dielectric layers and the second dielectric layers, wherein the first conductive line comprises:
a first line segment disposed between the first dielectric layers;
a second line segment disposed between the second dielectric layers;
first conductive vias stacked on each other and penetrating the first dielectric layers, wherein the first conductive vias are connected to the first line segment; and
second conductive vias stacked on each other and penetrating the second dielectric layers, wherein the second conductive vias are connected to the first conductive vias and the second line segment.

2. The circuit substrate as claimed in claim 1, wherein the first material is different from the second material.

3. The circuit substrate as claimed in claim 1, wherein the first thickness is smaller than the second thickness.

4. The circuit substrate as claimed in claim 1, wherein a ratio of the second thickness to the first thickness is greater than or equal to 1.5.

5. The circuit substrate as claimed in claim 1, wherein the first line segment has a first line length, the second line segment has a second line length, and the second line length is between 20% and 85% of the sum of the first line length and the second line length.

6. The circuit substrate as claimed in claim 1, wherein the first line segment has a first line width, the second line segment has a second line width, and the second line width is larger than the first line width.

7. The circuit substrate as claimed in claim 1, wherein the first line segment is located at a first level, the second line segment is located at a second level, and the circuit substrate further comprises:
a first ground layer located at the first level, wherein the first ground layer is separated from the first line segment and surrounds the first line segment;
a second ground layer located at the second level, wherein the second ground layer is separated from the second line segment and surrounds the second line segment; and
ground vias stacked on each other and penetrating the first dielectric layers and the second dielectric layers, wherein the ground vias are connected to the first ground layer and the second ground layer.

8. The circuit substrate as claimed in claim 1, wherein the second dielectric layers are disposed between the first surface of the core substrate and the first dielectric layers.

9. The circuit substrate as claimed in claim 1, wherein the second dielectric layers are disposed on the first surface and the second surface of the core substrate, and some of the second dielectric layers are disposed between the first surface of the core substrate and the first dielectric layer.

10. The circuit substrate as claimed in claim 1, wherein the second line segment is disposed on the first surface or the second surface of the core substrate.

11. The circuit substrate as claimed in claim 1, wherein the core substrate has a core conductive through-hole that penetrates the core substrate and is connected to the second conductive vias.

12. The circuit substrate as claimed in claim 11, further comprising:
third dielectric layers disposed on the second surface of the core substrate, wherein each of the third dielectric layers is formed of the first material and has the first thickness,
wherein the first conductive line comprises:
third conductive vias stacked on each other and penetrating the third dielectric layers, wherein the third conductive vias are connected to the second conductive vias.

13. The circuit substrate as claimed in claim 1, wherein the first conductive line comprises a single transmission line coupled to a transmission port for transmitting a first signal from the transmission port, or coupled to a reception port for transmitting the first signal to the reception port.

14. The circuit substrate as claimed in claim 1, further comprising:
a second conductive line disposed in the first dielectric layers and the second dielectric layers, wherein the second conductive line comprises:
a third line segment disposed between the first dielectric layers, wherein a projection of the third line segment is substantially parallel with a projection of the first line segment;
a fourth line segment disposed between the second dielectric layers, wherein a projection of the fourth line segment is substantially parallel with a projection of the second line segment;
fourth conductive vias stacked on each other and penetrating the first dielectric layers, wherein the fourth conductive vias are connected to the third line segments; and
fifth conductive vias stacked on each other and penetrating the second dielectric layers, wherein the fifth conductive vias are connected to the fourth conductive vias and the fourth line segments.

15. The circuit substrate as claimed in claim 14, wherein a line length of the fourth line segment is greater than a line length of the second line segment.

16. The circuit substrate as claimed in claim 14, wherein the first conductive line and the second conductive line are located at different levels, the first conductive line is a single transmission line coupled to a transmission port for transmitting a first signal transmitted from the transmission port, and the second conductive line is another single transmission line coupled to a reception port for transmitting the second signal to the reception port.

17. The circuit substrate as claimed in claim 14, wherein the first conductive line and the second conductive line are located at the same level, and the first conductive line and the second conductive line are coupled to a transmission port or a reception port to form a pair of differential signal transmission lines.

18. The circuit substrate as claimed in claim 14, wherein the first conductive line and the second conductive line are located at different levels, further comprising:
a third conductive line disposed in the first dielectric layers and the second dielectric layers, wherein the third conductive line is substantially parallel with the first conductive line, and the first conductive line has the same structure as the third conductive line; and
a fourth conductive line disposed in the first dielectric layers and the second dielectric layers, wherein the fourth conductive line is substantially parallel with the second conductive line, and the second conductive line has the same structure as the fourth conductive line.

19. The circuit substrate as claimed in claim 18, wherein the first conductive line and the third conductive line are coupled to a transmission port to form a first pair of differential signal transmission lines, and wherein the second conductive line and the fourth conductive line are coupled to a reception port to form a second pair of differential signal transmission lines.

20. The circuit substrate as claimed in claim 19, wherein:
the first line segments of the first conductive line and the third conductive line are located at a first level,
the second line segments of the first conductive line and the third conductive line are located at a second level,
the third line segments of the second conductive line and the fourth conductive line are located at a third level, and
the fourth line segments of the second conductive line and the fourth conductive line are located at a fourth level.
